(19) United States
(12) Patent Application Publication
(10) Pub. No.: US 2021/0184657 A1
(43) Pub. Date: Jun. 17, 2021

(54) Apparatus for Asynchronous Latch with Improved Performance and Associated Methods

(71) Applicant: Silicon Laboratories Inc., Austin, TX (US)

(72) Inventor: Chester Yu, Austin, TX (US)

(21) Appl. No.: 16/710,981

(22) Filed: Dec. 11, 2019

(51) Int. Cl. H03K 3/037; H03K 19/20

(52) U.S. Cl. CPC H03K 3/037; G06F 1/04; H03K 19/20

(57) ABSTRACT

An apparatus includes an asynchronous D-latch. The asynchronous D-latch includes a first inverter and a second inverter coupled in an anti-parallel fashion. The asynchronous D-latch further includes a third inverter coupled to provide a complement of a data (D) input signal of the asynchronous D-latch to the first and second inverters. The asynchronous D-latch further includes a meta-stability filter coupled to the first and second inverters.

### TECHNICAL FIELD

The disclosure relates generally to electronic storage circuitry or devices and, more particularly, to apparatus for latches, and associated methods.

### BACKGROUND

Advances in information processing has resulted in increasing demands for processing power. Examples include faster and more capable processors, faster graphics or video hardware, and faster and larger memory.

With advances in technology, an increasing number of circuit elements have been integrated into devices, such as integrated circuits (ICs). Furthermore, a growing number of devices, such as ICs, or subsystems, have been integrated into products. With developments such as the Internet of Things (IoT), this trend is expected to continue.

The growing number of circuit elements, devices, subsystems, etc., has also resulted in a corresponding increase in the amount of digital or mixed-signal circuitry. Such circuitry includes storage devices, such as flip-flops and latches. Thus, an improvement in the storage devices results in an improvement in the overall digital or mixed-signal circuitry because of the increasing use/number of storage devices.

The description in this section and any corresponding figure(s) are included as background information materials. The materials in this section should not be considered as an admission that such materials constitute prior art to the present patent application.

### SUMMARY

A variety of apparatus and associated methods are contemplated according to exemplary embodiments. According to one exemplary embodiment, an apparatus includes an asynchronous D-latch. The asynchronous D-latch includes a first inverter and a second inverter coupled in an anti-parallel fashion. The asynchronous D-latch further includes a third inverter coupled to provide a complement of a data (D) input signal of the asynchronous D-latch to the first and second inverters. The asynchronous D-latch further includes a meta-stability filter coupled to the first and second inverters.

According to another exemplary embodiment, an apparatus includes an asynchronous clock gate circuit to gate a clock (CLK) signal. The asynchronous clock gate circuit includes a first inverter and a second inverter coupled in an anti-parallel fashion. The asynchronous clock gate circuit further includes a third inverter coupled to provide a complement of an enable signal of the asynchronous clock gate circuit to the first and second inverters. The asynchronous clock gate circuit further includes a meta-stability filter coupled to the first and second inverters.

According to another exemplary embodiment, an apparatus includes a synchronizer to synchronize an input signal to a clock signal of a clock domain. The synchronizer comprising a single flip-flop, which includes an asynchronous D-latch. The asynchronous D-latch includes a first inverter and a second inverter coupled in an anti-parallel fashion. The asynchronous D-latch further includes a third inverter coupled to provide a complement of a data (D) signal of the synchronizer to the first and second inverters. The asynchronous D-latch further includes a meta-stability filter coupled to the first and second inverters.

### BRIEF DESCRIPTION OF THE DRAWINGS

The appended drawings illustrate only exemplary embodiments and therefore should not be considered as limiting the scope of the application or of the claimed subject-matter. Persons of ordinary skill in the art will appreciate that the disclosed concepts lend themselves to other equally effective embodiments. In the drawings, the same numeral designators used in more than one drawing denote the same, similar, or equivalent functionality, components, or blocks.

FIG. 1 shows a circuit arrangement for a latch according to an exemplary embodiment.

FIG. 2 shows a circuit arrangement for a clock gate circuit according to an exemplary embodiment.

FIG. 3 shows a circuit arrangement for a synchronizer circuit according to an exemplary embodiment.

FIG. 4 shows a circuit arrangement for a circuit employing multiple clock domains.

FIG. 5 shows a circuit arrangement for synchronizing signals according to an exemplary embodiment.

FIG. 6 shows a circuit arrangement for synchronizing signals according to another exemplary embodiment.

FIG. 7 shows a circuit arrangement for an IC according to an exemplary embodiment.

### DETAILED DESCRIPTION

The disclosed concepts relate generally to storage devices or circuits. More specifically, the disclosed concepts provide apparatus and associated methods for latches with improved performance, such as asynchronous data-latches (D-latches).

In conventional D-latches, when the data (D) changes at the same time as the enable (E) signal falls (or within a sufficiently small period of time), the D-latch can go meta-stable. During the meta-stable period, the output (Q) and complement output (QB) of the D-latch can be undetermined. In order to avoid meta-stability, the value of the D signal should not change at the same time or close to when the EN signal falls.

D-latches according to various embodiments have improved performance by virtue of using a meta-stability filter, and allow the D signal to change at any time. Such D-latches may be used to realize clock gates, i.e., a circuit to gate a clock signal, without using two flip-flops to enable the clock gate, as is typically the case with conventional approaches.

Furthermore, signal synchronizer circuits may be realized. More specifically, a single stage flip-flop, built with asynchronous D-latches according to various embodiments, can replace a two-flip-flop synchronizer for meta-stability resolution.

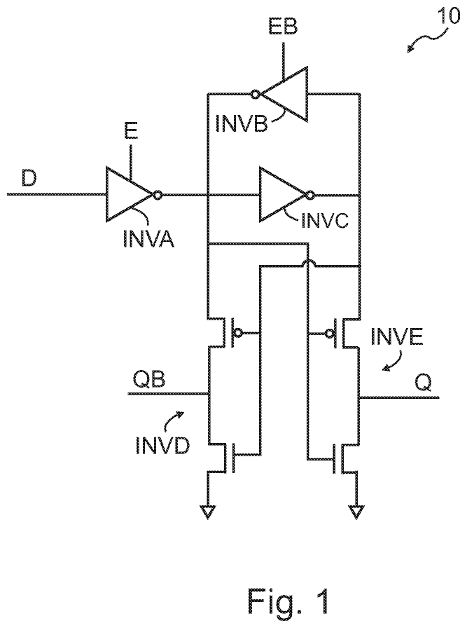

FIG. 1 shows a circuit arrangement for a latch 10 according to an exemplary embodiment. The asynchronous D-latch 10 has an enable (E), a complement enable (EB), and a data (D) input signals. The latch 10 has Q and QB outputs, similar to a conventional D-latch.

Referring again to FIG. 1, latch 10 includes an inverter INVA that receives the D input of the latch 10. When enabled by the E signal, the inverter INVA provides a complement of the D signal to the input of inverter INVC. The inverter INVC is coupled in an anti-parallel or cross-coupled manner to inverter INVB. In other words, the output of the inverter INVC is coupled to the input of the inverter INVB, and the output of the inverter INVB is coupled to the input of the inverter INVC.

The inverter INVB is enabled or disabled in response to the complement enable signal (EB). Thus, when the E signal has a logic 0 value, the EB signal has a logic 1 value, which enables the inverter INVB, and vice-versa.

The latch 10 further includes a meta-stability filter. The meta-stability filter helps to avoid or prevent a meta-stable condition in the latch 10 and, thus, improves the operation of the latch 10. In the embodiment shown, the meta-stability filter includes an inverter INVD, and an inverter INVE. Note that the latch 10 does experience meta-stability under some circumstances. The meta-stability filter (the inverters INVD and INVE) prevents a meta-stable condition from propagating to the outputs of the latch 10. While input and output nodes of INVC are meta-stable, Q and QB are both low, because both p-channel devices in the inverters INVD and INVE are in the cut-off region. As such, the outputs remain in a known stable state until meta-stability resolves. When resolved, either Q or QB will rise to a stable high state.

The inverter INVD includes a p-type metal oxide semiconductor (PMOS) transistor coupled to an n-type MOS (NMOS) transistor. The gates of the PMOS and NMOS transistors in the inverter INVD are coupled to the input of the inverter INVB and to the output of the inverter INVC.

The source of the PMOS transistor in the inverter INVD is coupled to the outputs of the inverters INVA and INVB and to the input of the inverter INVC. The source of the NMOS transistor in the inverter INVD is coupled to the ground potential. The drains of the PMOS and NMOS transistors in the inverter INVD are coupled to the QB output of the latch 10.

Similarly, the inverter INVE includes a PMOS transistor coupled to an NMOS transistor. The gates of the PMOS and NMOS transistors in the inverter INVE are coupled to the outputs of the inverters INVA and INVB, and to the input of the inverter INVC.

The source of the PMOS transistor in the inverter INVE is coupled to the output of the inverter INVC and to the input of the inverter INVB. The source of the NMOS transistor in the inverter INVE is coupled to the ground potential. The drains of the PMOS and NMOS transistors in the inverter INVE are coupled to the Q output of the latch 10.

The latch 10 has two modes or phases of operation, the transparent phase, and the latching phase. During the transparent phase, changes in the value of the D signal are transmitted to the Q and QB outputs of the latch 10. More specifically, during this mode, the enable (E) signal has a logic value of 1, and the EB signal has a value of 0.

If the value of the D signal changes to logic 1 during the transparent phase, then the output of the inverter INVA goes to logic 0, and the output of the inverter INVC goes to logic 1. The inverter INVB is disabled, with an output in tri-state. As the output of the inverter INVA drives the input of the inverter INVE, the Q output of the latch 10 goes to logic 1.

More specifically, the logic 1 output of the inverter INVC acts as a supply voltage for the inverter INVE, and the logic 0 output of the inverter INVA turns on the PMOS transistor (and turns off the NMOS transistor) in the inverter INVE, thus driving its output (the Q output of the latch 10) to logic 1. The logic 1 output of the inverter INVC turns on the NMOS transistor in the inverter INVD, and pulls the QB output of the latch 10 to logic 0. Thus, the Q output (logic 1) matches the value of the D signal (logic 1), and the Q and QB outputs of the latch 10 will have complementary values.

On the other hand, if the value of the D signal changes to logic 0 during the transparent phase, then the output of the inverter INVA goes to logic 1, and the output of the inverter INVC goes to logic 0. As the output of the inverter INVA (logic 1) drives the gate of the NMOS transistor in the inverter INVE, the NMOS transistor turns on and pulls the Q output of the latch 10 to logic 0.

The logic 1 output of the inverter INVA acts as a supply voltage for the inverter INVD, and the logic 0 output of the inverter INVC turns on the PMOS transistor (and turns off the NMOS transistor) in the inverter INVD, thus driving its output (the QB output of the latch 10) to logic 1. Thus, the Q output (logic 0) matches the value of the D signal (logic 0), and the Q and QB outputs of the latch 10 will have complementary values.

Conversely, during the latching phase, the latched value of the D signal is provided at the Q and QB outputs of the latch 10. During the latching phase, changes in the value of the D signal do not result in changes in the values of the output signals Q and QB.

More specifically, during the latching phase, the enable (E) signal has a logic 0 value. As a result, any changes at the input of the inverter INVA (i.e., changes in the D signal) are not propagated through the rest of the latch 10, because the output of the inverter INVA is in tri-state condition. In this mode, the inverters INVB and INVC form a feedback loop that maintains the value before the E signal transitioned to the logic 0 value. Similarly, the inverters INVD and INVE likewise maintain whatever values the Q and QB outputs had before the E signal transitioned to the logic 0 value.

Typically, the conditions for meta-stability exist when the latch 10 makes a transition from the transparent mode to the latching mode. In this situation, the E signal makes transitions from logic 1 to logic 0 (EB makes a transition from logic 0 to logic 1), and the D input changes within a certain window of time (the meta-stability window).

Under those circumstances, the output of the inverter INVA may not finish changing (e.g., logic 0 to logic 1), but instead may assume a mid-rail value, i.e., a voltage value between the voltages corresponding to the logic 0 and logic 1 values. The inverters INVC and INVB experience a similar phenomenon, causing the input and output of INVC to be at a mid-rail value or voltage.

As a result, both of the PMOS transistors in the inverters INVD and INVE are in cut-off region until the input and output values of the inverter INVC have enough separation in voltage (threshold voltage (VT) separation) such that the outputs of the inverters INVD and INVE resolve to known states. At that point, the Q and QB outputs of the latch 10 will also have known states. Before resolution is achieved, both of the NMOS transistors are turned on, while both PMOS transistors are turned off, which drive both of the Q and QB outputs to a low state, awaiting resolution.

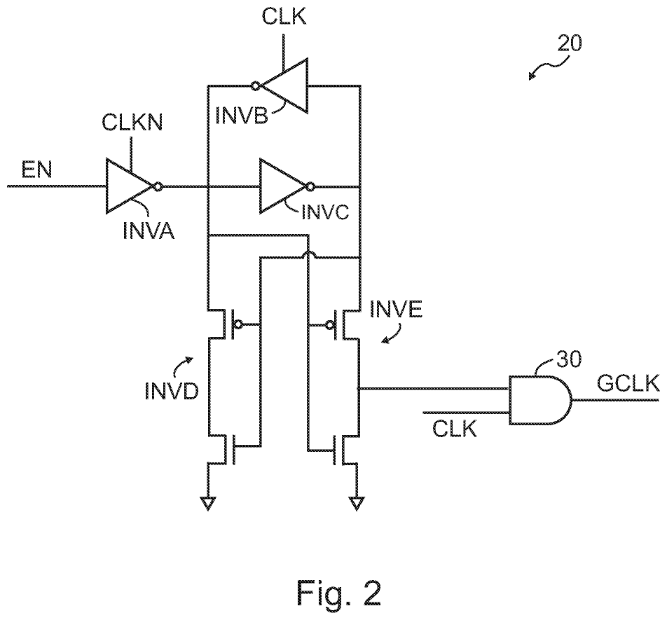

Another aspect of the disclosure relates to clock gate circuits. FIG. 2 shows a circuit arrangement for an asynchronous clock gate 20 according to an exemplary embodiment. The asynchronous clock gate 20 is built around the asynchronous latch 10, shown in FIG. 1.

Referring again to FIG. 2, the asynchronous clock gate 20 includes the latch 10 (see FIG. 10). Rather than using a data (D) signal, the input of the inverter INVA is driven by an enable (EN) signal, which allows gating the clock (CLK) signal. The complement of the CLK signal, labeled CLKN, drives the enable input of the inverter INVA. The CLK signal drives the enable input of the inverter INVB. The CLK and the CLKN signals enable or disable the inverters INVB and INVA, respectively.

The output of the inverter INVE drives one input of an AND gate 30. The CLK signal drives another input of the AND gate 30. The output of the AND gate 30, labeled GCLK, provides the gated clock signal, i.e., a gated version of the CLK signal.

In the asynchronous clock gate 20 shown in FIG. 2, the EN signal can change at any time with respect to the CLK signal (and/or the CLKN signal). In other words, changes in the EN signal may happen asynchronously with respect to the CLK and CLKN signals. Changes in the EN signal, even if asynchronously, do not cause glitches in the gated clock signal, i.e., the GCLK signal, provided that the high phase of the clock signal is sufficiently longer than the meta-stability resolution time of the meta-stability filter.

During the low phase of the CLK signal, the latch is operating in the transparent phase. A change of the EN signal from logic low to logic high propagates to the output of the inverter INVE as a logic low to high transition. This sequence enables the CLK signal immediately. Thus, the GCLK output will rise at the next rising edge of the CLK signal. Likewise, a change of the EN signal from logic high to logic low disables the CLK signal immediately. Consequently, the GCLK output will not rise at the next rising edge of the CLK signal. Because the EN signal changes while CLK is low, enabling and disabling of the GCLK output do not result in clock glitches.

During the high phase of CLK, the latch is operating in the latching phase. A change of the EN signal from logic low to logic high is blocked, thus preventing a change from low to high in the output of the inverter INVE. This prevents the enabling of the CLK signal during its high phase, which can potentially result in a clock glitch. Likewise, a change of the EN signal from logic high to logic low is also blocked, thus preventing a potential clock glitch. Subsequently, the EN signal is allowed to propagate to the output of the inverter INVE when the CLK signal changes from the high phase to the low phase. This delayed propagation of the changes in the EN signal enables or disables GCLK without creating clock glitches.

During the transition of the CLK signal from logic low to logic high, the latch can be in the meta-stable condition if the EN signal is changing. A change of the EN signal from logic low to logic high keeps the output of the inverter INVE at logic low until meta-stability resolution is complete. Meta-stability resolution can have two outcomes. If the output of the inverter INVE stays at logic low, the enabling of the GCLK output is delayed until the CLK signal falls. On the other hand, if the output of the inverter INVE rises, the GCLK output is enabled immediately during its high phase. This does not result in a clock glitch, as long as the resolution time is sufficiently shorter than the high phase of the CLK signal.

Similarly, a change of the EN signal from logic high to logic low causes the output of the inverter INVE output to go to logic low immediately until meta-stability resolution is complete. Meta-stability resolution has two outcomes. If the output of the inverter INVE stays at logic low, disabling of the GCLK output is immediate, and there are no more rising edges of the GCLK signal thereafter. If the output of the inverter INVE rises, the GCLK output propagates one more pulse, which is shortened. This does not result in a clock glitch as long as the resolution time is sufficiently shorter than the high phase of the CLK signal.

Note that, in a conventional clock gate, in order to prevent meta-stability in the latch and potential clock glitches, two-flop synchronizers are used to delay the changes in the EN signal to align with appropriate clock edges. Thus, this approach increases latency of the GCLK signal by two cycles of the CLK signal. Put another way, two pulses of the CLK signal are “swallowed” before the GCLK output is seen by down-stream logic. This in turn increases power-consumption, as the clock sources are kept running longer.

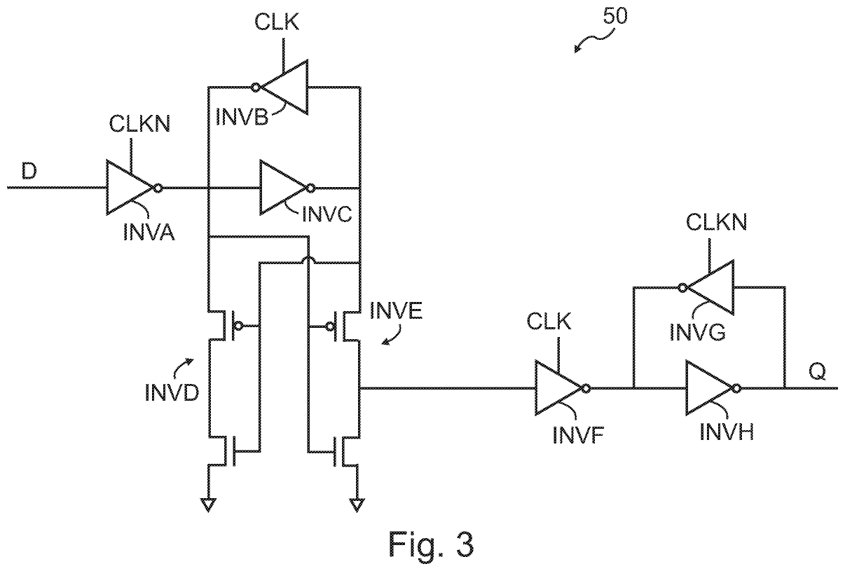

Another aspect of the disclosure relates to synchronizers. FIG. 3 shows a circuit arrangement for a synchronizer 50 according to an exemplary embodiment. Note that, in contrast to conventional approaches, the synchronizer 50 uses a single flop (single flip-flop), rather than two flops used conventionally.

Referring again to FIG. 3, the synchronizer 50 is based on the latch 10 (see FIG. 1). More specifically, the synchronizer 50 includes the latch 10 (see FIG. 1), plus three additional inverters, i.e., the inverters INVF, INVG, and INVH. In the synchronizer 50, the complement clock signal (CLKN) enables or disables the inverters INVA and INVG, whereas the clock signal (CLK) enables or disables the inverters INVB and INVF.

The output of the inverter INVE, drives the input of the inverter INVF. The output of the inverter INVF drives the input of the inverter INVH. The inverter INVH and the inverter INVG are coupled in an anti-parallel or cross-coupled fashion. In other words, the output of the inverter INVG drives the input of the inverter INVH. Conversely, the output of the inverter INVH drives the input of the inverter INVG.

When the D input changes sufficiently long before the rising edge of the CLK signal (setup time is met), it is propagated to the output of the inverter INVE and blocked by the inverter INVF. At the next rising edge of the CLK signal, the latched value of the output of the inverter INVE is propagated to the Q output, while the D input is blocked by INVA (changes in the D input are blocked from propagating).

When the D input changes sufficiently long after the rising edge of the CLK signal (hold time is met), it is blocked by the inverter INVA until the next falling edge of the CLK signal. At that time, it is allowed to propagate to the output of the inverter INVE, and is blocked by the inverter INVF, while the Q output is driven by the feedback loop formed by the inverters INVG and INVH. At the next rising edge of the CLK signal, the latched value of the output signal of the inverter INVE is propagated to the Q output, while the D input is blocked by the inverter INVA.

When the D input changes during the setup time and hold time window, meta-stability occurs at the input and the output of the inverter INVC. The output of the inverter INVE goes to logic low immediately, while awaiting for meta-stability resolution. This causes the Q to go to logic low. When the meta-stability resolution completes, if the output of the inverter INVE rises, the Q output will also rise. As long as the sum of the meta-stability resolution time, the CLK-to-Q delay time, and the down-stream logic propagation time is shorter than the clock period, the flip-flops in the down-stream logic will meet their setup time requirements.

Note that conventional meta-stability mitigation techniques use two-flop synchronizers. When the first flop goes meta-stable due to setup/hold timing violation, the second flop prevents the propagation of its output to down-stream logic. As long as meta-stability resolves within one clock period, the second flop will propagate the resolved value one clock cycle later. In synchronizers according to various embodiments, however, the two flops of the conventional approach are reduced to two latches. This allows resolved data to propagate within the first clock cycle, instead of adding a one cycle data delay.

Note that, compared to two-flop conventional synchronizers, the synchronizer 50 in FIG. 3 uses a single flop. Use of a single flop reduces the power consumption of the synchronizer 50, and also saves IC area, etc., as persons of ordinary skill in the art will understand. As a result of using a single flop, a single cycle of the clock signal CLK allows synchronization of the D signal to the CLK signal. Furthermore, the synchronizer 50 includes the latch 10 (see FIG. 1), with its meta-stability filter and attendant attributes, as described above.

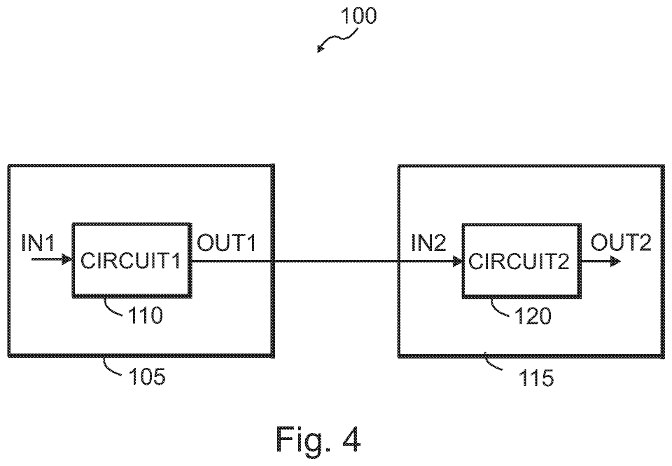

The synchronizer 50 may be used to synchronize a given signal (D) to a clock domain, as exemplified by the use of the clock signal CLK. In some situations, the signal provided to the D input may originate from a different clock domain than the clock domain of the CLK signal. FIG. 4 illustrates this situation.

More specifically, referring to FIG. 4, a circuit arrangement 100 includes two clock domains, labeled 105 and 115, respectively. A circuit 110, labeled CIRCUIT1, operates in clock domain 105. The circuit 110 accepts one or more input signals, labeled IN1, and generates an output signal, labeled OUT1 (although more than one output signal may be generated, as persons of ordinary skill in the art will understand).

The signal OUT1 is provided to the clock domain 115. More specifically, the signal OUT1 from the circuit 110 is provided as an input signal (IN2) to a circuit 120, labeled CIRCUIT2. The circuit 120 operates in the clock domain 115. In response to the input signal IN2, the circuit 120 generates an output signal OUT2 (although more than one output signal may be generated, as persons of ordinary skill in the art will understand).

Note that the circuit 110 operates in a different clock domain (i.e., the clock domain 105) than does the circuit 120 (i.e., it operates in the clock domain 115). The output signal of the circuit 110 should be synchronized to the clock domain 115 to facilitate proper operation of the circuit 120.

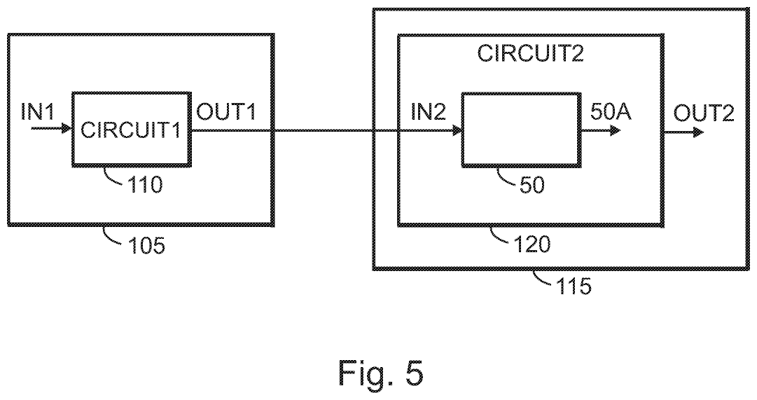

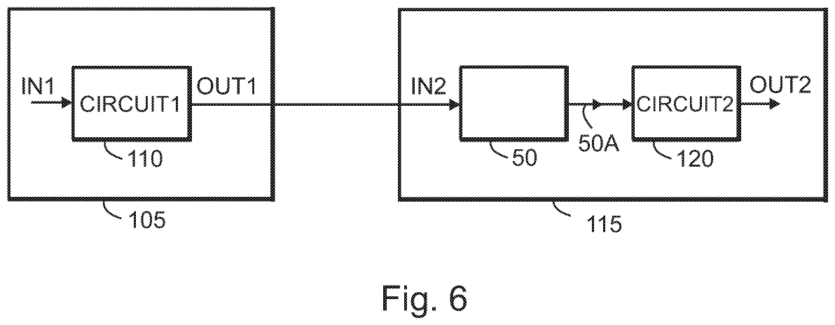

In other words, given that, generally speaking, the output signal of the circuit 110 is asynchronous with respect to the clock domain 115, the output signal OUT1 should be synchronized to the clock domain 115. The synchronizer 50 (see FIG. 3) may be used to do so, as shown in FIGS. 5 and 6.

FIG. 5 shows a scenario where the circuit 120, operating in the clock domain 115, includes the synchronizer 50. In this situation, the output signal of the circuit 110 is provided as input signal IN2 to the synchronizer 50.

In response to the clock signal (not shown) of the clock domain 115, the synchronizer 50 synchronizes the input signal IN2 to the clock domain 115, and provides the synchronized signal as output signal 50A of the synchronizer 50. Other circuitry in the circuit 120 may use the output signal 50A to perform additional operations, as it has been synchronized to the clock domain 115. The result of the operations may be used internally in the circuit 120, or may be provided as output signal OUT2.

FIG. 6 shows a scenario where the synchronizer 50 is separate from the circuit 120. In this scenario, the synchronizer 50 receives the output signal of the circuit 110 as input signal IN2. In response to the clock signal (not shown) of the clock domain 115, the synchronizer 50 synchronizes the input signal IN2 to the clock domain 115, and provides the synchronized signal as output signal 50A of the synchronizer 50. The circuit 120 may use the output signal 50A to perform additional operations, as it has been synchronized to the clock domain 115. The result of the operations may be used internally in the circuit 120, or may be provided as output signal OUT2.

Asynchronous D-latches, such as described above in connection with exemplary embodiments, may be used in a variety of circuits, blocks, subsystems, and/or systems. For example, in some embodiments, such asynchronous D-latches, asynchronous clock gates (based on the asynchronous D-latches), and/or synchronizers (based on the asynchronous D-latches) may be integrated in an IC, such as a microcontroller unit (MCU).

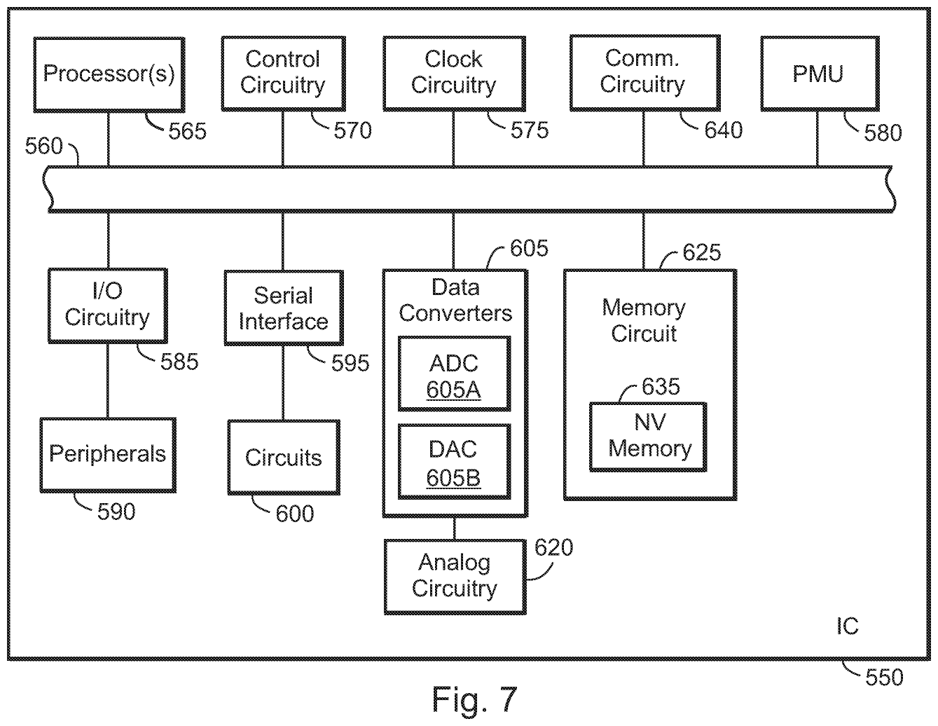

FIG. 7 shows a block diagram of an IC 550 according to an exemplary embodiment. The IC 550 includes a variety of circuits, subsystems, systems, blocks, etc., as described below.

One or more of such circuits, subsystems, systems, blocks, etc. may use one or more asynchronous D-latches, asynchronous clock gates (based on the asynchronous D-latches), as desired. Furthermore, in some embodiments, one or more circuits (or subsystems, systems, blocks, etc.) in the IC 550 may operate in a different clock domain than one or more circuits (or subsystems, systems, blocks, etc.) in the IC 550. In such situations, signals traversing clock domain boundaries may be synchronized to the destination clock domain, using synchronizers (based on the asynchronous D-latches), as described above.

The circuit arrangement in FIG. 7 includes an IC 550, which constitutes or includes an MCU. IC 550 includes a number of blocks (e.g., processor(s) 565, data converter 605, I/O circuitry 585, etc.) that communicate with one another using a link 560. In exemplary embodiments, link 560 may constitute a coupling mechanism, such as a bus, a set of conductors or semiconductor elements (e.g., traces, devices, etc.) for communicating information, such as data, commands, status information, and the like.

IC 550 may include link 560 coupled to one or more processors 565, clock circuitry 575, and power management circuitry or power management unit (PMU) 580. In some embodiments, processor(s) 565 may include circuitry or blocks for providing information processing (or data processing or computing) functions, such as central-processing units (CPUs), arithmetic-logic units (ALUs), and the like. In some embodiments, in addition, or as an alternative, processor(s) 565 may include one or more DSPs. The DSPs may provide a variety of signal processing functions, such as arithmetic functions, filtering, delay blocks, and the like, as desired.

Clock circuitry 575 may generate one or more clock signals that facilitate or control the timing of operations of one or more blocks in IC 550. Clock circuitry 575 may also control the timing of operations that use link 560, as desired. In some embodiments, clock circuitry 575 may provide one or more clock signals via link 560 to other blocks in IC 550. Clock circuitry 575 may provide mechanisms for gating one or more clock signals to one or more blocks in IC 550 by using one or more asynchronous clock gates 20, as described above.

In some embodiments, PMU 580 may reduce an apparatus's (e.g., IC 550) clock speed, turn off the clock, reduce power, turn off power, disable (or power down or place in a lower power consumption or sleep or inactive or idle state), enable (or power up or place in a higher power consumption or normal or active state) or any combination of the foregoing with respect to part of a circuit or all components of a circuit, such as one or more blocks in IC 550. Further, PMU 580 may turn on a clock, increase a clock rate, turn on power, increase power, or any combination of the foregoing in response to a transition from an inactive state to an active state (including, without limitation, when processor(s) 565 make a transition from a low-power or idle or sleep state to a normal operating state).

Link 560 may couple to one or more circuits 600 through serial interface 595. Through serial interface 595, one or more circuits or blocks coupled to link 560 may communicate with circuits 600. Circuits 600 may communicate using one or more serial protocols, e.g., SMBUS, I²C, SPI, and the like, as person of ordinary skill in the art will understand.

Link 560 may couple to one or more peripherals 590 through I/O circuitry 585. Through I/O circuitry 585, one or more peripherals 590 may couple to link 560 and may therefore communicate with one or more blocks coupled to link 560, e.g., processor(s) 565, memory circuit 625, etc.

In exemplary embodiments, peripherals 590 may include a variety of circuitry, blocks, and the like. Examples include I/O devices (keypads, keyboards, speakers, display devices, storage devices, timers, sensors, etc.). Note that in some embodiments, some peripherals 590 may be external to IC 550. Examples include keypads, speakers, and the like. Peripherals 590 may have different clock domains than does IC 550. In such situations, one or more synchronizers 50 may be used to synchronize one or more signals crossing clock domain boundaries.

In some embodiments, with respect to some peripherals, I/O circuitry 585 may be bypassed. In such embodiments, some peripherals 590 may couple to and communicate with link 560 without using I/O circuitry 585. In some embodiments, such peripherals may be external to IC 550, as described above.

Link 560 may couple to analog circuitry 620 via data converter(s) 605. Data converter(s) 605 may include one or more ADCs 605A and/or one or more DACs 605B.

ADC(s) 605A receive analog signal(s) from analog circuitry 620, and convert the analog signal(s) to a digital format, which they communicate to one or more blocks coupled to link 560. Conversely, DAC(s) 605B receive digital signal(s) from one or more blocks coupled to link 560, and convert the digital signal(s) to analog format, which they communicate to analog circuitry 620.

Analog circuitry 620 may include a wide variety of circuitry that provides and/or receives analog signals. Examples include sensors, transducers, and the like, as person of ordinary skill in the art will understand. In some embodiments, analog circuitry 620 may communicate with circuitry external to IC 550 to form more complex systems, sub-systems, control blocks or systems, feedback systems, and information processing blocks, as desired.

Control circuitry 570 couples to link 560. Thus, control circuitry 570 may communicate with and/or control the operation of various blocks coupled to link 560 by providing control information or signals. In some embodiments, control circuitry 570 also receives status information or signals from various blocks coupled to link 560. In addition, in some embodiments, control circuitry 570 facilitates (or controls or supervises) communication or cooperation between various blocks coupled to link 560.

In some embodiments, control circuitry 570 may initiate or respond to a reset operation or signal. The reset operation may cause a reset of one or more blocks coupled to link 560, of IC 550, etc., as person of ordinary skill in the art will understand. For example, control circuitry 570 may cause PMU 580, and any other desired circuitry to reset to an initial or known state.

In exemplary embodiments, control circuitry 570 may include a variety of types and blocks of circuitry. In some embodiments, control circuitry 570 may include logic circuitry, finite-state machines (FSMs), or other circuitry to perform operations such as the operations described above.

Communication circuitry 640 couples to link 560 and also to circuitry or blocks (not shown) external to IC 550. Through communication circuitry 640, various blocks coupled to link 560 (or IC 550, generally) can communicate with the external circuitry or blocks (not shown) via one or more communication protocols. Examples of communications include USB, Ethernet, and the like. In exemplary embodiments, other communication protocols may be used, depending on factors such as design or performance specifications for a given application, as person of ordinary skill in the art will understand.

As noted, memory circuit 625 couples to link 560. Consequently, memory circuit 625 may communicate with one or more blocks coupled to link 560, such as processor(s) 565, control circuitry 570, I/O circuitry 585, etc.

Memory circuit 625 provides storage for various information or data in IC 550, such as operands, flags, data, instructions, and the like, as persons of ordinary skill in the art will understand. Memory circuit 625 may support various protocols, such as double data rate (DDR), DDR2, DDR3, DDR4, and the like, as desired.

In some embodiments, memory read and/or write operations by memory circuit 625 involve the use of one or more blocks in IC 550, such as processor(s) 565. A direct memory access (DMA) arrangement (not shown) allows increased performance of memory operations in some situations. More specifically, DMA (not shown) provides a mechanism for performing memory read and write operations directly between the source or destination of the data and memory circuit 625, rather than through blocks such as processor(s) 565.

Memory circuit 625 may include a variety of memory circuits or blocks. In the embodiment shown, memory circuit 625 includes non-volatile (NV) memory 635. In addition, or instead, memory circuit 625 may include volatile memory (not shown), such as random access memory (RAM). NV memory 635 may be used for storing information related to performance, control, or configuration of one or more blocks in IC 550. Memory circuit 625, including NV memory 635, may use one or more latches 10 to store one or more data, control, and/or status signals, as desired.

Referring to the figures, persons of ordinary skill in the art will note that the various blocks shown might depict mainly the conceptual functions and signal flow. The actual circuit implementation might or might not contain separately identifiable hardware for the various functional blocks and might or might not use the particular circuitry shown. For example, one may combine the functionality of various blocks into one circuit block, as desired. Furthermore, one may realize the functionality of a single block in several circuit blocks, as desired. The choice of circuit implementation depends on various factors, such as particular design and performance specifications for a given implementation. Other modifications and alternative embodiments in addition to the embodiments in the disclosure will be apparent to persons of ordinary skill in the art. Accordingly, the disclosure teaches those skilled in the art the manner of carrying out the disclosed concepts according to exemplary embodiments, and is to be construed as illustrative only. Where applicable, the figures might or might not be drawn to scale, as persons of ordinary skill in the art will understand.

The particular forms and embodiments shown and described constitute merely exemplary embodiments. Persons skilled in the art may make various changes in the shape, size and arrangement of parts without departing from the scope of the disclosure. For example, persons skilled in the art may substitute equivalent elements for the elements illustrated and described. Moreover, persons skilled in the art may use certain features of the disclosed concepts independently of the use of other features, without departing from the scope of the disclosure.

1. An apparatus, comprising:
an asynchronous D-latch, comprising:
a first inverter and a second inverter coupled in an anti-parallel fashion;
a third inverter coupled to provide a complement of a data (D) input signal of the asynchronous D-latch to the first and second inverters; and
a meta-stability filter coupled to the first and second inverters.

2. The apparatus according to claim 1, wherein the meta-stability filter comprises a fourth inverter and a fifth inverter.

3. The apparatus according to claim 2, wherein an input of the fourth inverter is coupled to an output of the first inverter.

4. The apparatus according to claim 2, wherein an output of the fifth inverter comprises a Q output of the asynchronous D-latch.

5. The apparatus according to claim 1, wherein the asynchronous D-latch has an enable (E) signal.

6. The apparatus according to claim 5, wherein the enable signal enables or disables the third inverter.

7. The apparatus according to claim 5, wherein a complement (EB) of the enable signal enables or disables the second inverter.

8-20. (canceled)

21. A method of latching a signal in an asynchronous D-latch comprising first, second, and third inverters, the method comprising:
using the third inverter to generate a complement of a data (D) input signal of the asynchronous D-latch;
providing the complement of the data input signal of the asynchronous D-latch to the first and second inverters; and
using a meta-stability filter coupled to the first and second inverters;
wherein the first and second inverters are coupled in an anti-parallel configuration.

22. The method according to claim 21, wherein the meta-stability filter comprises a fourth inverter and a fifth inverter.

23. The method according to claim 22, wherein an input of the fourth inverter is coupled to an output of the first inverter.

24. The method according to claim 23, wherein an input of the fifth inverter is coupled to the output of the second inverter.

25. The method according to claim 22, further comprising providing a Q output of the asynchronous D-latch from an output of the fifth inverter.

26. The method according to claim 25, further comprising providing a complement-Q (QB) output of the asynchronous D-latch from an output of the fourth inverter.

27. The method according to claim 21, further comprising using an enable (E) signal to enable or disable the asynchronous D-latch.

28. The method according to claim 27, further comprising using the enable signal to enable or disable the third inverter.

29. The method according to claim 27, further comprising using a complement (EB) of the enable signal to enable or disable the second inverter.

30. The apparatus according to claim 3, wherein an input of the fifth inverter is coupled to the output of the second inverter.

31. The apparatus according to claim 4, wherein an output of the fourth inverter comprises a complement-Q (QB) output of the asynchronous D-latch.

32. The apparatus according to claim 2, wherein the fourth inverter comprises a p-type metal oxide semiconductor (PMOS) transistor coupled to an n-type MOS (NMOS) transistor.

33. The apparatus according to claim 2, wherein the fifth inverter comprises a p-type metal oxide semiconductor (PMOS) transistor coupled to an n-type MOS (NMOS) transistor.
